(19) United States
(12) Patent Application Publication
(10) Pub. No.: US 2026/0107765 A1
(43) Pub. Date: Apr. 16, 2026

(54) SEMICONDUCTOR DEVICE

(71) Applicant: WAVEPIA CO., LTD., Gyeonggi-do (KR)

(72) Inventors: Sang Hun LEE, Hwaseong-si (KR); Sang Yeol LEE, Hwaseong-si (KR); Sang Su KIM, Hwaseong-si (KR)

(73) Assignee: WAVEPIA CO., LTD., Gyeonggi-do (KR)

(21) Appl. No.: 19/270,600

(22) Filed: Jul. 16, 2025

(30) Foreign Application Priority Data
Oct. 15, 2024 (KR) 10-2024-0140108

(51) Int. Cl. H01L 23/34; G01K 1/02; G01K 7/22

(52) U.S. Cl. CPC H10W 40/00; G01K 1/026; G01K 7/22

(57) ABSTRACT

The present invention relates to a semiconductor device. The semiconductor device of the present invention includes a semiconductor substrate, a semiconductor layer disposed on the semiconductor substrate, a plurality of resistors disposed in the semiconductor layer, at least one electrode layer disposed on the semiconductor layer, and a first temperature measurement pad, a second temperature measurement pad, and a third temperature measurement pad that are disposed on the semiconductor layer, wherein the plurality of resistors are electrically connected to at least one of the first temperature measurement pad, the second temperature measurement pad, and the third temperature measurement pad, and heat is transferred to the plurality of resistors through the semiconductor layer, thereby allowing measurement of temperatures of the semiconductor layer and the highest-temperature heat source of the semiconductor device based on resistance values of the plurality of resistors.

### CROSS-REFERENCE TO RELATED APPLICATION

This application claims priority to and the benefit of Korean Patent Application No. 2024-0140108, filed on Oct. 15, 2024, the disclosure of which is incorporated herein by reference in its entirety.

### BACKGROUND

### 1. Field of the Invention

The present invention relates to a semiconductor device, and more particularly, to a semiconductor device including a plurality of resistors disposed in a semiconductor layer.

### 2. Discussion of Related Art

As technologies in fields such as electric vehicles, autonomous vehicles, wireless communication including 5G or 6G, satellite communication, and high-resolution radar have advanced in recent years, semiconductor devices used in these fields are required to enable high-frequency signal processing, high-speed operation, and high output. With the increasing operating speed and output of semiconductor devices, transistors disposed in the semiconductor devices switch at higher speeds, and larger currents flow through their channels. In this process, the power consumption of the semiconductor devices increases, and the amount of heat generated by the semiconductor devices increases accordingly.

When the amount of heat generated by the semiconductor devices increases, various parts constituting the semiconductor devices may undergo degradation due to stress caused by excessive temperature variations. For example, cracks may occur in each of the layers constituting the semiconductor device, the lifespan of semiconductor elements may be shortened, or switching performance may degrade due to a decrease in electron mobility.

Accordingly, heat sink structures and cooling systems have been proposed to effectively dissipate heat generated by the semiconductor device. However, as the switching speed of the semiconductor device increases and its size becomes smaller, conventional heat sink structures and cooling systems may be less efficient in dissipating the heat generated by the semiconductor device. Further, various temperature measurement methods have been attempted to monitor heat generation states in semiconductor devices, but it has been difficult to accurately measure the temperature of the semiconductor devices, as the measured value often reflects the temperature of air already heated due to the heat generated by the semiconductor devices. That is, in recent semiconductor devices, it is difficult to accurately determine where heat is concentrated and the extent to which heat is generated. Accordingly, conventional structures or devices for measuring and dissipating heat generated in semiconductor devices may fail to promptly measure actual heat sources of the semiconductor devices or respond quickly thereto, resulting in performance degradation and a shortened lifespan of the semiconductor elements over time.

Accordingly, there is a need for a technology to address the above-described issues.

Meanwhile, the above-described background art is technical information possessed by the inventor for derivation of the present invention or acquired by the inventor during the derivation of the present invention, and is not necessarily considered to be a known art open to the general public prior to the filing of the present invention.

### PRIOR-ART DOCUMENT

### Patent Document

(Patent Document 1) Korean Laid-Open Patent Publication No. 10-2009-0074548 (Jul. 7, 2009)

### SUMMARY OF THE INVENTION

The present invention is directed to providing a semiconductor device capable of accurately measuring the amount of heat generated by the highest-temperature heat source of the semiconductor device by calculating a temperature through a resistor disposed in a semiconductor layer.

The present invention is also directed to providing a semiconductor device that has a small volume and low manufacturing cost by directly connecting a resistor to a temperature measurement pad without a separate wiring structure.

The present invention is also directed to providing a semiconductor device capable of more accurately measuring a temperature of a semiconductor layer inside the semiconductor device by covering upper portions of a plurality of resistors with temperature measurement pads and an insulator.

The present invention is also directed to providing a semiconductor device capable of more accurately calculating a temperature of a semiconductor layer by allowing at least one resistor to receive heat of the semiconductor layer through a via connected to the semiconductor layer.

Objectives of the present invention are not limited to the above-described objectives, and other objectives that are not described herein will be apparently understood by those skilled in the art from the following description.

According to an aspect of the present invention, there is provided a semiconductor device including a semiconductor substrate, a semiconductor layer disposed on the semiconductor substrate, a plurality of resistors disposed in the semiconductor layer, at least one electrode layer disposed on the semiconductor layer, and a first temperature measurement pad, a second temperature measurement pad, and a third temperature measurement pad that are disposed on the semiconductor layer, wherein the plurality of resistors are electrically connected to at least one of the first temperature measurement pad, the second temperature measurement pad, and the third temperature measurement pad.

According to another feature of the present invention, the plurality of resistors may include a first resistor, a second resistor, and a third resistor, wherein the first resistor and the second resistor may be connected in parallel, one side of each of the first resistor and the second resistor may be electrically connected to the first temperature measurement pad, the other side of each of the first resistor and the second resistor may be electrically connected to the second temperature measurement pad and one side of the third resistor, and the other side of the third resistor may be electrically connected to the third temperature measurement pad.

According to still another feature of the present invention, the first resistor, the second resistor, and the third resistor may have the same resistance value.

According to yet another feature of the present invention, the first temperature measurement pad may be disposed on each of the first resistor and the second resistor, the second temperature measurement pad may be disposed on each of the first resistor, the second resistor, and the third resistor, and the third temperature measurement pad may be disposed on the third resistor.

According to yet another feature of the present invention, the semiconductor device may further include a first insulator disposed between the first temperature measurement pad and the second temperature measurement pad, and a second insulator disposed between the second temperature measurement pad and the third temperature measurement pad, wherein the first temperature measurement pad, the second temperature measurement pad, and the first insulator may cover an entire upper surface of each of the first resistor and the second resistor, and the second temperature measurement pad, the third temperature measurement pad, and the second insulator may cover an entire upper surface of the third resistor.

According to yet another feature of the present invention, the at least one electrode layer may include a source electrode, a drain electrode, and a gate electrode.

According to yet another feature of the present invention, the semiconductor device may further include a ground layer disposed below the semiconductor substrate, a first via disposed between the source electrode and the ground layer, and a second via disposed between the third resistor and the ground layer, wherein the first via may have thermal conductivity and electrical conductivity, and may be electrically connected to the source electrode and the ground layer.

According to yet another feature of the present invention, the second via may have thermal conductivity and may be thermally connected to the third resistor and the ground layer. According to yet another feature of the present invention, the first resistor, the second resistor, and the third resistor may be mesa resistors.

According to yet another feature of the present invention, the semiconductor device may further include at least one transistor, wherein the at least one transistor may include a channel disposed in the semiconductor layer.

According to yet another feature of the present invention, the semiconductor device may further include a fourth resistor disposed on the semiconductor layer, and a fourth temperature measurement pad and a fifth temperature measurement pad disposed at both sides of the fourth resistor, wherein the fourth temperature measurement pad may be electrically connected to one side of the fourth resistor, and the fifth temperature measurement pad may be electrically connected to the other side of the fourth resistor.

### BRIEF DESCRIPTION OF THE DRAWINGS

The above and other objects, features, and advantages of the present invention will become more apparent to those of ordinary skill in the art by describing exemplary embodiments thereof in detail with reference to the accompanying drawings, in which:

FIG. 1 is a top view of a semiconductor device according to one embodiment of the present disclosure;

FIG. 2 is a cross-sectional view of the semiconductor device of FIG. 1 taken along line II-II′;

FIG. 3 is an enlarged view of portion III of the semiconductor device of FIG. 1;

FIG. 4 is a block diagram for describing connection relationships between a plurality of resistors and a plurality of temperature measurement pads in portion III of the semiconductor device of FIG. 1;

FIG. 5 is a cross-sectional view of the semiconductor device of FIG. 1 taken along line V-V′;

FIG. 6 is a flowchart illustrating a method of calculating a temperature of a semiconductor layer based on a temperature of a series resistor according to the present disclosure;

FIG. 7 is a flowchart illustrating a method of calculating a temperature of the semiconductor layer based on temperatures of parallel resistors and a series resistor according to the present disclosure;

FIG. 8 is a top view illustrating a semiconductor device according to another embodiment of the present disclosure; and

FIG. 9 is a cross-sectional view of the semiconductor device of FIG. 8 taken along line IX-IX′.

### DETAILED DESCRIPTION OF EXEMPLARY EMBODIMENTS

Advantages and features of the present invention and implementation methods thereof will be clarified through the following embodiments described with reference to the accompanying drawings. However, the present invention is not limited to the embodiments described below and may be embodied with a variety of different modifications. The embodiments are merely provided to allow those skilled in the art to completely understand the scope of the present invention, and the present invention is defined only by the scope of the claims.

The figures, dimensions, ratios, angles, numbers, and the like disclosed in the drawings for describing the embodiments of the present invention are merely illustrative and are not limited to matters shown in the present invention. Further, in describing the present invention, detailed descriptions of well-known technologies will be omitted when it is determined that they may unnecessarily obscure the gist of the present invention. Terms such as “including,” “having,” and “composed of” used herein are intended to allow other elements to be added unless the terms are used with the term “only.” Any references to the singular may include the plural unless expressly stated otherwise.

Components are interpreted to include an ordinary error range even if not expressly stated.

Although the terms “first,” “second,” and the like may be used herein to describe various components, the components are not limited by the terms. These terms are used only to distinguish one component from another component. Therefore, a first component described below may be a second component within the technological scope of the present invention.

Unless otherwise indicated herein, throughout the specification, like reference numerals refer to like elements.

Features of various embodiments of the present invention may be partially or overall coupled to or combined with each other, and may be variously inter-operated with each other and driven technically as those skilled in the art can sufficiently understand. The embodiments of the present invention may be implemented independently from each other, or may be implemented together in co-dependent relationship.

The present invention will be described in detail with reference to the accompanying drawings.

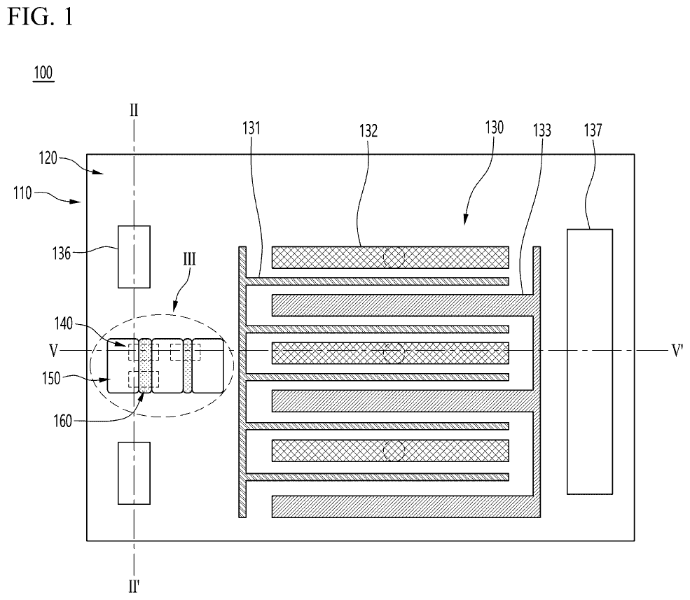

FIG. 1 is a top view of a semiconductor device according to one embodiment of the present disclosure.

Referring to FIG. 1, a semiconductor device 100 includes a semiconductor substrate 110, a semiconductor layer 120, a transistor 130, a gate electrode 131, a source electrode 132, a drain electrode 133, a resistor part 140, a temperature measurement pad part 150, and an insulating part 160. In addition, the semiconductor device 100 may further include a gate pad 136 and a drain pad 137.

The semiconductor device 100 is a device that controls or processes electrical signals. Specifically, the semiconductor device 100 may be a semiconductor device used to process high-frequency or high-power signals. For example, the semiconductor device 100 may be a radio frequency (RF) semiconductor or a power semiconductor used for transmitting, receiving, or delivering high-frequency or high-power signals in fields such as 5G/6G communication, satellite and radar systems, RF power amplifiers, or power conversion systems.

The semiconductor substrate 110 may include various materials depending on the type and required characteristics of the semiconductor device 100. Specifically, the semiconductor substrate 110 may include various materials depending on the lattice constant, thermal conductivity, or thermal expansion coefficient of the semiconductor layer 120 of the semiconductor device 100. In addition, the semiconductor substrate 110 may include various materials depending on the manufacturing process, costs, and mass production feasibility of the semiconductor device 100. For example, the semiconductor substrate 110 may include Si, SiC, Al₂O₃, GaAs, GaN, InP, InAs, or InSb.

The semiconductor layer 120 is disposed on at least a portion of an upper surface of the semiconductor substrate 110. Specifically, the semiconductor layer 120 may be disposed on only a portion of the upper surface or on the entire upper surface of the semiconductor substrate 110. According to various embodiments of the present invention, the semiconductor layer 120 may be included in the semiconductor substrate 110. For example, a portion of the doped semiconductor substrate 110 may function as the semiconductor layer 120 and a channel of the transistor. In the present embodiment, descriptions will be given based on an example in which the semiconductor layer 120 is disposed on the entire upper surface of the semiconductor substrate 110.

The semiconductor layer 120 includes a semiconductor material. Specifically, the semiconductor layer 120 may include a compound semiconductor. For example, the semiconductor layer 120 may include GaN, AlGaN, or GaAs. According to various embodiments of the present invention, the semiconductor layer 120 may include a plurality of heterojunction semiconductor materials. For example, the semiconductor layer 120 may include a heterojunction of a plurality of semiconductor materials having different energy bandgaps, such as GaN and AlGaN. Accordingly, a two-dimensional electron gas (2DEG) may be disposed between GaN and AlGaN in the semiconductor layer 120, so that the semiconductor layer 120 may include a channel of a GaN high electron mobility transistor (HEMT).

At least one transistor 130 is disposed on the semiconductor layer 120. Although a plurality of transistors 130 are illustrated in FIG. 1, the number of transistors 130 is not limited thereto. For example, the semiconductor device 100 may include only one transistor 130, or may include at least one transistor array in which a plurality of transistors 130 are arranged in an array.

The transistor 130 may be of various types. For example, the transistor 130 may be a HEMT, a junction field-effect transistor (JFET), a metal-oxide-semiconductor field-effect transistor (MOSFET), or a GaN FET. In particular, the transistor 130 may include a GaN FET or a GaN HEMT, which can provide high-speed switching performance and high current density, thereby enabling the semiconductor device 100 to exhibit excellent performance in power amplification and high-frequency applications.

The transistor 130 includes a channel (not shown), the gate electrode 131, the source electrode 132, and a drain electrode 133. The channel of the transistor 130 is a conductive path between the source electrode 132 and the drain electrode 133, and a conductivity thereof is determined according to a voltage applied to the gate electrode 131. High heat may be generated in the channel of the transistor 130 due to current flow and switching operation of the transistor 130. In particular, when the transistor 130 operates at high power and high frequency, the heat generated in the channel due to the switching operation of the transistor 130 may further increase. Accordingly, when the transistor 130 operates, the channel may be the highest-temperature region in the semiconductor device 100.

The channel of the transistor 130 may be disposed or formed in a partial region of the semiconductor layer 120. Accordingly, heat generated in the channel of the transistor 130 may be conducted through the semiconductor layer 120. In particular, when the semiconductor layer 120 and the channel include a material with high thermal conductivity, such as GaN, the heat generated in the channel may be effectively conducted through the semiconductor layer 120.

The gate electrode 131, the source electrode 132, and the drain electrode 133 may be disposed on the semiconductor layer 120. The source electrode 132 and the drain electrode 133 may be spaced apart from each other with the gate electrode 131 interposed therebetween. Referring to FIG. 1, at least one transistor 130 may have a form in which the source electrode 132 and the drain electrode 133 are disposed to be spaced apart from each other, and the gate electrode 131 is disposed between the source electrode 132 and the drain electrode 133.

A gate line and a drain line may be disposed in a direction perpendicular to a direction in which each of the electrodes of at least one transistor 130 extends. The gate line may be electrically connected to at least one gate electrode 131, and the drain line may be electrically connected to at least one drain electrode 133.

The gate pad 136 and the drain pad 137 may be disposed on the semiconductor layer 120 to be spaced apart from the transistor 130. Specifically, the gate pad 136 and the drain pad 137 may be respectively disposed at left and right edges of the semiconductor device 100.

The gate electrode 131 and the gate line may be electrically connected to the gate pad 136, and the drain electrode 133 and the drain line may be electrically connected to the drain pad 137. Accordingly, the gate electrode 131 may receive a gate control signal through the gate line and the gate pad 136, and the drain electrode 133 may receive or transmit an electrical signal through the drain line and the drain pad 137.

Referring to FIG. 1, the resistor part 140 includes at least one resistor. Specifically, the resistor part 140 may include a plurality of resistors. For example, the resistor part 140 may include three resistors. In the present embodiment, descriptions will be given based on an example in which the resistor part 140 includes three resistors.

The resistor included in the resistor part 140 may be a resistive element whose resistance value changes according to a temperature change. Accordingly, a temperature change of the semiconductor device 100 may be monitored based on a change in the resistance value of the resistor.

The resistor part 140 may include a material whose electrical properties change according to the temperature. Specifically, the resistor part 140 may include a material having a high temperature coefficient of resistivity (TCR). For example, the resistor part 140 may include a polymer-based or ceramic-based material of a positive temperature coefficient (PTC) thermistor, a metal oxide material of a negative temperature coefficient (NTC) thermistor, or a GaN material. As the resistor part 140 includes a material with a high TCR, the temperature of the resistor part 140 may be calculated more accurately based on a resistance value of the resistor part 140.

The resistor part 140 may include resistors having the same resistance value. Specifically, the resistors included in the resistor part 140 may be designed to have the same material and the same resistance value. Accordingly, even when a process error occurs in some of the resistors, an average resistance value of the resistors may converge to a designed resistance value.

The resistors of the resistor part 140 may have various shapes. Specifically, although various shapes are possible, the resistors included in the resistor part 140 may be formed in the same shape. For example, the resistors included in the resistor part 140 may all have a thin-film shape formed through a deposition process or a protruding shape, such as a mesa shape, formed through an etching process. For example, the resistor part 140 may include mesa resistors whose shape and size are precisely controlled through semiconductor processes. Accordingly, the resistor part 140 may be formed using existing semiconductor manufacturing processes, thereby achieving low manufacturing costs.

The resistor part 140 is disposed above the semiconductor substrate 110. Specifically, the resistor part 140 may be disposed in a partial region of the semiconductor layer 120. That is, the resistor part 140 may be disposed in the same layer as the semiconductor layer 120. Accordingly, the resistor part 140 may effectively receive heat from the semiconductor layer 120. Thus, temperatures of the semiconductor layer 120 and the channel of the transistor 130 may be more accurately measured based on a temperature of the resistor part 140 disposed in the semiconductor layer 120. Furthermore, when the resistor part 140 includes a plurality of resistors, individual resistance values of the respective resistors may be measured in consideration of the arrangement positions of the resistors and their relationships with other layers, thereby enabling even small temperature changes to be calculated. Accordingly, by individually measuring the temperatures of the resistors, not only can small temperature changes in desired portions of the semiconductor device 100 be calculated, but accurate temperatures can also be measured in real time. In addition, by measuring individual resistance values of the resistors along with the total resistance value of the resistor part 140, the temperature of the semiconductor device 100 can be calculated in real time, and the resolution of temperature measurement can be improved.

Referring to FIG. 1, the temperature measurement pad part 150 includes at least one temperature measurement pad. Specifically, the temperature measurement pad part 150 may include a plurality of temperature measurement pads. In the present embodiment, descriptions will be given based on an example in which the temperature measurement pad part 150 includes three temperature measurement pads.

The temperature measurement pad part 150 is disposed on the semiconductor layer 120. Specifically, the temperature measurement pad part 150 may be disposed in a partial upper region of the resistor part 140 and a partial upper region of the semiconductor layer 120. According to various embodiments of the present invention, the temperature measurement pad part 150 may be disposed at a predetermined distance from the resistor part 140 and may be connected to the resistor part 140 via wiring. For example, as shown in FIG. 1, the temperature measurement pad part 150 is directly disposed on the resistor part 140, thereby omitting the wiring connecting between the temperature measurement pad part 150 and the resistor part 140 and reducing the manufacturing cost and die size of the semiconductor device 100.

The temperature measurement pad part 150 includes a conductive material. Specifically, the temperature measurement pad part 150 may include a material having high electrical conductivity such as a metal. Accordingly, the temperature measurement pad part 150 may be electrically connected to the resistor part 140. For example, the temperature measurement pad part 150 may be directly disposed on the resistor part 140 to be electrically connected thereto. Thus, a temperature calculation module (not shown) outside the semiconductor device 100 may be electrically connected to the temperature measurement pad part 150 and may apply a current to the resistor part 140, thereby measuring a resistance value of the resistor part 140 and calculating a temperature of the resistor part 140 based on a change in the resistance value.

In addition, the temperature measurement pad part 150 may include a material having low thermal conductivity. Specifically, the thermal conductivity of the temperature measurement pad part 150 may be lower than that of the semiconductor layer 120. Accordingly, since the resistor part 140 covered by the temperature measurement pad part 150 is isolated from external air and cannot dissipate heat through the temperature measurement pad part 150, the temperature of the resistor part 140 more closely follows changes in the temperature of the semiconductor layer 120. Thus, the temperature measurement pad part 150 may suppress upward heat dissipation from the resistor part 140, thereby allowing the resistor part 140 to exhibit a temperature closer to those of the semiconductor layer 120 and the highest-temperature heat source of the semiconductor device 100. The temperatures of the semiconductor layer 120 and the highest-temperature heat source of the semiconductor device 100 may be more accurately measured through the temperature of the resistor part 140.

Although the resistor part 140 and the temperature measurement pad part 150 are illustrated as being disposed to the left of the transistor 130 in FIG. 1, the positions of the resistor part 140 and the temperature measurement pad part 150 are not limited thereto. As shown in FIG. 1, on a plane of the semiconductor device 100, the resistor part 140 may be disposed above, below, to the left of, or to the right of the transistor 130. That is, the resistor part 140 may be disposed in an empty space outside the transistor 130 in the semiconductor device 100.

The resistor part 140 and the temperature measurement pad part 150 are disposed at predetermined distances from the transistor 130, the gate line, and the drain line. Specifically, when the part that is closest to the resistor part 140 and the temperature measurement pad part 150 among the electrodes of the transistor 130, the gate line, and the drain line is referred to as the nearest pattern, a minimum distance between the resistor part 140 and the temperature measurement pad part 150 and the transistor 130, the gate line, and the drain line may be greater than or equal to 0.5 times a width of the nearest pattern and less than or equal to 5 times the width of the nearest pattern. For example, as shown in FIG. 1, when the resistor part 140 and the temperature measurement pad part 150 are disposed to the left of the transistor 130, the shortest distance between the temperature measurement pad part 150 and the gate line may be greater than or equal to 0.5 times a width of the gate line and less than or equal to 5 times the width of the gate line. The resistor part 140 and the temperature measurement pad part 150 may be disposed close enough to the transistor 130 to enable accurate measurement of the temperature of the channel of the transistor 130, and may be spaced apart from the transistor 130 by a certain distance or more so as not to interfere with the manufacturability and RF characteristics of the semiconductor device 100.

Referring to FIG. 1, the insulating part 160 may be disposed on an upper surface of the semiconductor layer 120. Specifically, the insulating part 160 may be disposed between the temperature measurement pad parts 150 and above the resistor part 140. More specifically, the insulating part 160 may be disposed to cover the entire upper surface of the resistor part 140, which is not covered by the temperature measurement pad part 150. Accordingly, since the resistor part 140 is completely isolated from the external air by the temperature measurement pad part 150 and the insulating part 160, the resistor part 140 may have a temperature closer to that of the semiconductor layer 120 and the channel of the transistor 130.

A temperature calculation module (not shown) may calculate a temperature of the resistor part 140 by measuring a resistance value of the resistor part 140 of the semiconductor device 100, and may calculate temperatures of the semiconductor layer 120 and the highest-temperature heat source of the semiconductor device 100 based on the calculated temperature. The temperature calculation module (not shown) may include a resistance measuring part, a processor, and a memory. Further, the temperature calculation module (not shown) may further include an input part and an output part. The temperature calculation module (not shown) may be a temperature calculation device located outside the semiconductor device 100. According to various embodiments of the present invention, the temperature calculation module (not shown) may be a circuit connected to the temperature measurement pad part 150 of the semiconductor device 100.

The resistance measuring part may include a probe or a terminal. By inputting and outputting an electrical signal through the probe or terminal, the resistance measuring part may measure the resistance value of the resistor part 140 of the semiconductor device. Specifically, the resistance measuring part may apply a current to the temperature measurement pad part 150 via the probe or terminal and measure a voltage drop caused by the resistor part 140, thereby measuring the resistance value of the resistor part 140.

The memory may store various data or parameters transmitted by the processor. For example, the memory may store a lookup table including information on temperatures of the resistor part 140, the semiconductor layer 120, and the channel of the transistor 130, corresponding to a designed resistance value of the resistor part 140. In addition, the memory may store various relationship equations calculated by the processor. For example, the memory may include a relationship equation between the resistance value and temperature according to a TCR.

The processor may perform various operations using data received from the resistance measuring part and the memory. For example, the processor may calculate a process error of a series resistor based on a difference in resistance values between the parallel resistors and the series resistor, and may calculate an accurate temperature of the series resistor by reflecting the process error.

The input part may transmit user-input data to the processor. For example, the input part may receive update information for the lookup table and time point information for measuring the resistance value of the resistor part 140 from a user, and transmit the received information to the processor.

The output part may receive various types of data from the processor and output the various types of data in various formats. For example, the output part may be a display panel. The output part may output the data received from the processor as a table or visualize the data in the form of a graph.

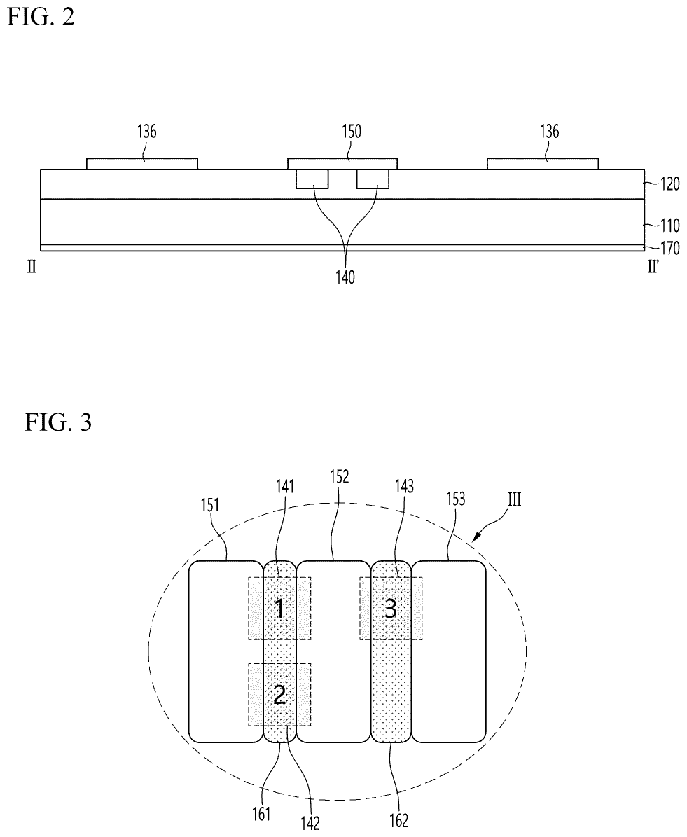

FIG. 2 is a cross-sectional view of the semiconductor device of FIG. 1 taken along line II-II′.

Referring to FIG. 2, the semiconductor device 100 includes a lower ground layer 170 disposed below the semiconductor substrate 110. The lower ground layer 170 may be disposed on at least a portion of a lower surface of the semiconductor substrate 110. Specifically, the lower ground layer 170 may be disposed only in regions below the transistor 130 and the resistor part 140. In the present embodiment, descriptions will be given based on an example in which the lower ground layer 170 is disposed on the entire lower surface of the semiconductor substrate 110.

The lower ground layer 170 includes a conductive material. For example, the lower ground layer 170 may include a metal having high electrical conductivity. In addition, the lower ground layer 170 may include a material having high thermal conductivity. Accordingly, heat generated in the channel of the transistor 130 may be transmitted to the lower ground layer 170 through the semiconductor layer 120 and the semiconductor substrate 110, and then dissipated to the outside.

The lower ground layer 170 may be grounded. In this case, the lower ground layer 170 may function as a ground electrode of the transistor 130.

Although the semiconductor layer 120 is illustrated as a single layer in FIG. 2, the number of layers constituting the semiconductor layer 120 is not limited thereto. The semiconductor layer 120 may include at least one layer. Specifically, the semiconductor layer 120 may include a plurality of layers made of different materials. For example, a GaN semiconductor layer may be disposed on the entire surface of the semiconductor substrate 110, and an AlGaN semiconductor layer may be disposed only in a channel region of the transistor 130 on the GaN semiconductor layer.

As shown in FIG. 2, the resistor part 140 may be disposed in a partial region of the semiconductor layer 120. In FIG. 2, the resistor part 140 is illustrated as being inserted to a mid-depth of the semiconductor layer 120, but the resistor part 140 may be disposed to pass through the semiconductor layer 120. Since the resistor part 140 is formed to be disposed within the semiconductor layer 120 during a process of forming the semiconductor layer 120, an additional process for disposing the resistor part 140 in the semiconductor device 100 may be reduced, thereby reducing associated costs.

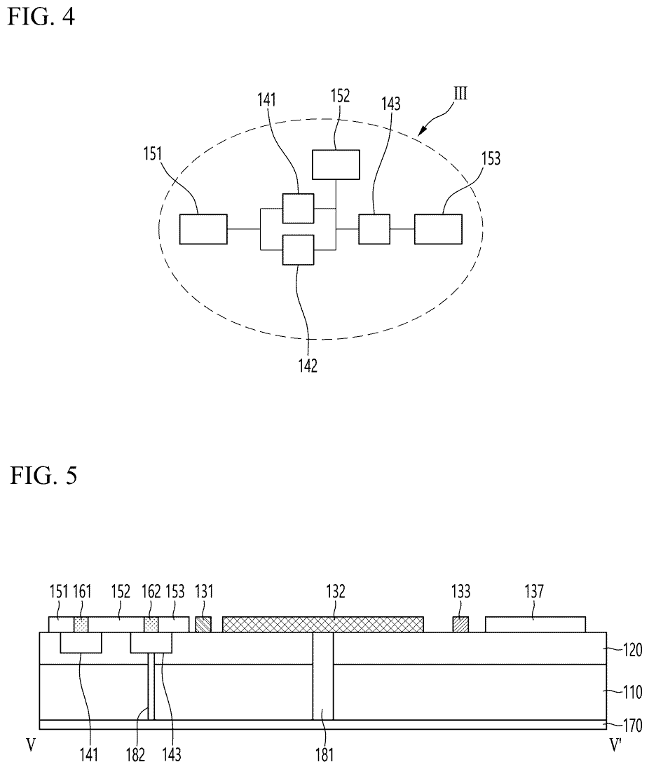

FIG. 3 is an enlarged view of portion III of the semiconductor device of FIG. 1. FIG. 4 is a block diagram for describing connection relationships between the plurality of resistors and the plurality of temperature measurement pads in portion III of the semiconductor device of FIG. 1.

Referring to FIGS. 3 and 4, the resistor part 140 includes a first resistor 141, a second resistor 142, and a third resistor 143, the temperature measurement pad part 150 includes a first temperature measurement pad 151, a second temperature measurement pad 152, and a third temperature measurement pad 153, and the insulating part 160 includes a first insulator 161 and a second insulator 162.

The first resistor 141 and the second resistor 142 are disposed in one direction. The third resistor 143 is disposed adjacent to the first resistor 141 and the second resistor 142. Specifically, the third resistor 143 may be disposed apart from the first resistor 141 and the second resistor 142 in a direction different from the direction in which the first resistor 141 and the second resistor 142 are disposed.

Referring to FIG. 3, the first temperature measurement pad 151, the second temperature measurement pad 152, and the third temperature measurement pad 153 may extend in one direction. The first temperature measurement pad 151, the second temperature measurement pad 152, and the third temperature measurement pad 153 may have the same shape and area, thereby having the same electrical characteristics.

The first temperature measurement pad 151 and the second temperature measurement pad 152 may be respectively disposed on portions of the first resistor 141 and the second resistor 142 that are disposed in one direction. For example, as shown in FIG. 3, on an upper surface of the semiconductor device 100, the first temperature measurement pad 151 may be disposed on left portions of upper surfaces of the first resistor 141 and the second resistor 142. The second temperature measurement pad 152 may be disposed on right portions of the upper surfaces of the first resistor 141 and the second resistor 142 and on a left portion of an upper surface of the third resistor 143. The third temperature measurement pad 153 may be disposed on a right portion of the upper surface of the third resistor 143. That is, the first temperature measurement pad 151 and the second temperature measurement pad 152 are disposed on the semiconductor layer 120 so as to partially overlap the first resistor 141 and the second resistor 142. In a similar manner, the second temperature measurement pad 152 and the third temperature measurement pad 153 are disposed on the semiconductor layer 120 so as to partially overlap the third resistor 143.

Referring to FIGS. 3 and 4, the first resistor 141, the second resistor 142, and the third resistor 143 are connected in parallel or in series through the first temperature measurement pad 151, the second temperature measurement pad 152, and the third temperature measurement pad 153. Specifically, the first resistor 141 and the second resistor 142 may be connected in parallel, and the first resistor 141 and the second resistor 142 may be connected in series with the third resistor 143. According to various embodiments of the present invention, the resistor part 140 may further include one or more additional resistors connected in parallel through the first temperature measurement pad 151 and the second temperature measurement pad 152. Accordingly, by being connected in parallel through the first temperature measurement pad 151 and the second temperature measurement pad 152 that extend in one direction, one or more additional resistor may be further included in the semiconductor device 100 without additional manufacturing processes or design changes.

Each of a parallel composite resistance value of the first resistor 141 and the second resistor 142, a resistance value of the third resistor 143, and a total equivalent resistance value of the first to third resistors 141, 142, and 143 may be measured. Specifically, the temperature calculation module (not shown) may measure the parallel composite resistance value of the first resistor 141 and the second resistor 142 through the first temperature measurement pad 151 and the second temperature measurement pad 152, may measure the resistance value of the third resistor 143 through the second temperature measurement pad 152 and the third temperature measurement pad 153, and may measure the total equivalent resistance value of the first to third resistors 141, 142, and 143 through the first temperature measurement pad 151 and the third temperature measurement pad 153. Accordingly, the temperatures of the resistors 141, 142, and 143 and the semiconductor layer 120 may be calculated based on the resistance values of the respective resistors 141, 142, and 143.

Referring to FIG. 3, at least one insulator may be disposed on the first resistor 141, the second resistor 142, or the third resistor 143. Specifically, the first insulator 161 may be disposed on the first resistor 141 and the second resistor 142, and the second insulator 162 may be disposed on the third resistor 143. More specifically, the first insulator 161, the first temperature measurement pad 151, and the second temperature measurement pad 152 may cover the entire upper surfaces of the first resistor 141 and the second resistor 142, and the second insulator 162, the second temperature measurement pad 152, and the third temperature measurement pad 153 may cover the entire upper surface of the third resistor 143. Accordingly, each of the first to third resistors 141, 142, and 143 may be completely isolated from external air, and thus may have a temperature closer to those of the semiconductor layer 120 and the highest-temperature heat source of the transistor 130.

FIG. 5 is a cross-sectional view of the semiconductor device of FIG. 1 taken along line V-V′.

Referring to FIG. 5, the semiconductor device 100 may include a first via 181 and a second via 182. The first via 181 and the second via 182 may extend in a direction perpendicular to a plane of the semiconductor substrate 110. The first via 181 and the second via 182 may be through-silicon vias (TSVs) that pass through the semiconductor substrate 110. The first via 181 and the second via 182 may include a thermally conductive material. For example, the first via 181 and the second via 182 may include a thermally conductive material filled in the holes, such as a thermally conductive metal, silicon oxide or polyimide mixed with thermally conductive fillers, epoxy, aluminum nitride (AlN), silicon carbide (SiC), beryllia (BeO), magnesium oxide (MgO), or boron nitride.

The first via 181 and the second via 182 may include an electrically conductive material. For example, the first via 181 and the second via 182 may include a metal material deposited inside the holes.

The first via 181 may vertically pass through the semiconductor substrate 110 between a lower surface of the source electrode 132 and an upper surface of the lower ground layer 170. Accordingly, the first via 181 may electrically or thermally connect the source electrode 132 to the lower ground layer 170. When the first via 181 electrically connects the source electrode 132 to the lower ground layer 170, the source electrode 132 may also be grounded. Thus, the semiconductor device 100 may not include a source pad for applying an electrical signal to the source electrode 132. Accordingly, the semiconductor device 100 may be miniaturized by an area corresponding to that for arranging the source pad, and more elements may be disposed in the semiconductor device 100, so that integration can be achieved. When the first via 181 thermally connects the source electrode 132 to the lower ground layer 170, heat generated in the semiconductor layer 120 may be transmitted to the source electrode 132 and the lower ground layer 170 through the first via 181 and then dissipated to the outside.

The second via 182 may vertically pass through the semiconductor substrate 110 between a lower surface of at least one of the resistors and the upper surface of the lower ground layer 170. For example, as shown in FIG. 5, the second via 182 may vertically pass through the semiconductor substrate 110 between a lower surface of the third resistor 143 and the upper surface of the lower ground layer 170. According to various embodiments of the present invention, at least one second via 182 may be disposed between a lower surface of each of the plurality of resistors and the lower ground layer 170. In the present embodiment, descriptions will be given based on an example in which the second via 182 is disposed between the lower surface of the third resistor 143 and the upper surface of the lower ground layer 170.

When the second via 182 includes a thermally conductive material, the third resistor 143 and the lower ground layer 170 may be thermally connected. Accordingly, thermal energy generated at the channel of the transistor 130 and conducted to the lower ground layer 170 through the first via 181 may be conducted to the third resistor 143 through the second via 182. Thus, the third resistor 143 may receive heat generated in the channel of the transistor 130 not only from the semiconductor layer 120 but also from the lower ground layer 170. As described above, the third resistor 143 may receive heat generated in the channel of the transistor 130 through two paths, so that the temperature of the third resistor 143 may become very similar to the temperature of the highest-temperature heat source of the semiconductor device 100. Accordingly, by measuring the resistance value of the third resistor 143, the temperature of the highest-temperature heat source of the semiconductor device 100 may be measured with high accuracy.

The second via 182 may not be electrically connected to the third resistor 143. For example, the second via 182 may include an insulating material having high thermal conductivity such as aluminum nitride (AlN), silicon carbide (SiC), beryllia (BeO), a polymer insulator mixed with a thermally conductive filler, or magnesium oxide (MgO). In addition, when the second via 182 includes an electrically conductive material, the second via 182 may be in contact with an insulating layer disposed on the lower surface of the third resistor 143. Specifically, two terminals of the third resistor 143 are electrically connected to the second temperature measurement pad 152 and the third temperature measurement pad 153, respectively, and the second via 182 is in contact with an insulated lower surface of the third resistor 143, so that the second via 182 may not be electrically connected to the third resistor 143. Accordingly, the third resistor 143 is not grounded, and a resistance value thereof may be measured through the second temperature measurement pad 152 and the third temperature measurement pad 153, thereby allowing a more accurate resistance value to be measured.

According to various embodiments of the present invention, the third temperature measurement pad 153 may be omitted as the second via 182 is electrically connected to the third resistor 143. In this case, the temperature calculation module (not shown) may measure a resistance value of the third resistor 143 by connecting one terminal to a ground point and the other terminal to one of the first temperature measurement pad 151 and the second temperature measurement pad 152. Accordingly, the first via 181 and the second via 182 of the semiconductor device 100 may be formed by the same process, thereby reducing manufacturing costs. In addition, by omitting the third temperature measurement pad 153, the semiconductor device 100 may be miniaturized by an area corresponding to that for arranging the temperature measurement pad, and more elements may be disposed in the semiconductor device 100, so that integration can be achieved.

The semiconductor device 100 according to the present embodiment includes the resistor part 140 disposed in the semiconductor layer 120, thereby enabling the temperature of the semiconductor layer 120 to be measured based on the temperature of the resistor part 140.

In addition, the semiconductor device 100 according to the present embodiment includes the resistor part 140, which is covered at the upper surface by the temperature measurement pad part 150 and the insulating part 160, or receives heat through the second via 182, thereby allowing more accurate measurement of the temperatures of the semiconductor layer 120 and the highest-temperature heat source of the semiconductor device 100 based on the temperature of the resistor part 140.

The semiconductor device 100 according to the present embodiment includes the resistor part 140 and the temperature measurement pad part 150, which are disposed at a certain distance from the transistor 130, thereby allowing heat generated at the channel of the transistor 130, which is the hottest heat source, to be transmitted to the resistor part 140 without loss, while not degrading the RF characteristics of the semiconductor device 100.

Since the resistor part 140 according to the present embodiment is formed in the same process as the process in which the semiconductor layer 120 is formed, the process and cost required to dispose the resistor part 140 in the semiconductor device 100 may be reduced.

The semiconductor device 100 according to the present embodiment may include the temperature measurement pads 151, 152, and 153 disposed on the resistor part 140 to connect the first to third resistors 141, 142, and 143 of the resistor part 140 in parallel or in series, thereby reducing the manufacturing cost and die area of the semiconductor device 100.

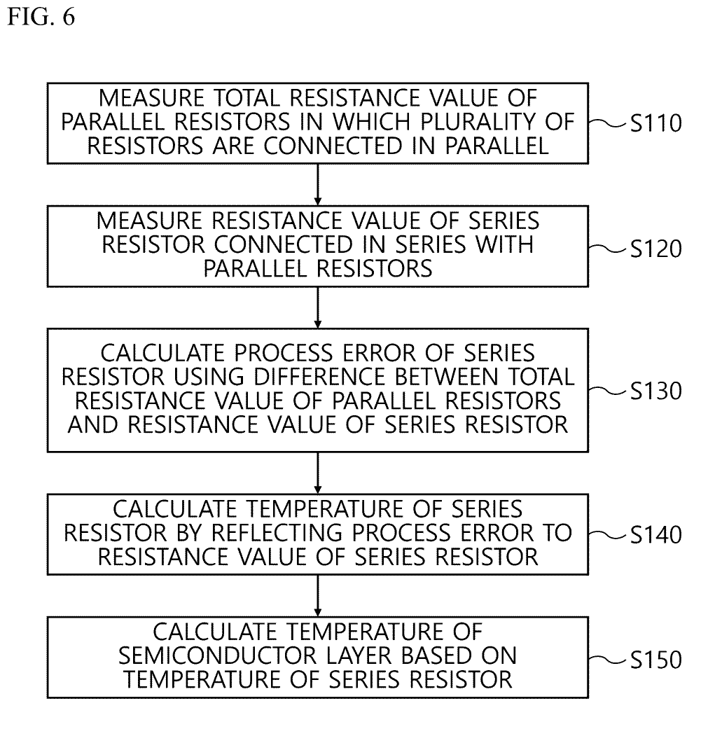

FIG. 6 is a flowchart illustrating a method of calculating a temperature of the semiconductor layer based on a temperature of a series resistor according to the present disclosure.

Referring to FIGS. 1 to 6, in operation S110, a total resistance value of parallel resistors in which a plurality of resistors are connected in parallel is measured. Specifically, the resistance measuring part of the temperature calculation module (not shown) may measure a parallel composite resistance value of the plurality of resistors connected in parallel at room temperature. In the present embodiment, descriptions will be given based on an example in which the resistance measuring part of the temperature calculation module (not shown) measures a parallel composite resistance value of the first resistor 141 and the second resistor 142 connected in parallel.

In operation S120, a resistance value of a series resistor connected in series with the parallel resistors is measured. Specifically, the resistance measuring part of the temperature calculation module (not shown) may measure a resistance value of the third resistor 143 at room temperature.

In operation S130, a process error of the series resistor is calculated using a difference between the total resistance value of the parallel resistors and the resistance value of the series resistor. Specifically, the processor of the temperature calculation module (not shown) calculates an average resistance value of each of the resistors connected in parallel based on the parallel composite resistance value and the number of resistors. The processor of the temperature calculation module (not shown) may calculate a process error of the third resistor 143 based on the difference by comparing the calculated average resistance value with the resistance value of the third resistor 143. In the case of a mesa resistor, a room-temperature resistance value of the resistor is determined by its geometric structure, such as the thickness, length, and width of the resistor, and thus both a resistance value prediction operation through simulation at a design stage and a precise resistance value measurement operation after manufacturing are essential. According to the embodiment of the present invention, as the number of resistors connected in parallel increases, an average resistance value that converges to a designed resistance value may be calculated, and a process error of a single resistor may be calculated based on the average resistance value.

In operation S140, the temperature of the series resistor is calculated by reflecting the process error to the resistance value of the series resistor. The memory of the temperature calculation module (not shown) may include a lookup table including a temperature of the resistor corresponding to a design resistance value of the resistor. The lookup table may be generated based on a relationship equation determined by a TCR of the resistor and the design resistance value. The processor of the temperature calculation module (not shown) may generate a new lookup table including a temperature corresponding to the resistance value of the third resistor 143 by applying an offset equal to the process error of the third resistor 143 to the lookup table including a temperature of the resistor corresponding to the design resistance value. Accordingly, the processor of the temperature calculation module (not shown) may calculate an accurate temperature of the third resistor 143 based on the lookup table reflecting the process error of the third resistor 143.

According to various embodiments of the present invention, the memory of the temperature calculation module (not shown) may include a relationship equation between the resistance value and temperature according to a TCR. Accordingly, the processor of the temperature calculation module (not shown) may calculate the temperature of the third resistor 143 based on the resistance value of the third resistor 143 using the relationship equation between the resistance value and temperature according to a TCR.

In operation S150, a temperature of the semiconductor layer is calculated based on the temperature of the series resistor. The memory of the temperature calculation module (not shown) may store a lookup table including a temperature of the semiconductor layer 120 and a temperature of the channel of the transistor 130 corresponding to the temperature of the third resistor 143. Accordingly, the processor of the temperature calculation module (not shown) may calculate the temperatures of the semiconductor layer 120 and the highest-temperature heat source of the semiconductor device 100 based on the temperature of the third resistor 143 using the lookup table including the temperature of the semiconductor layer 120 and the temperature of the channel of the transistor 130 corresponding to the temperature of the third resistor 143.

According to various embodiments of the present invention, when the semiconductor device 100 includes the third resistor 143 that receives heat from the channel of the transistor 130 through the semiconductor layer 120 and the second via 182, the third resistor 143 may have a temperature similar to that of the semiconductor layer 120 or the channel of the transistor 130, and thus the temperature of the third resistor 143 may be calculated as the temperature of the semiconductor layer 120 or the channel of the transistor 130. Accordingly, in the method of calculating the temperatures of the semiconductor layer 120 and the highest-temperature heat source of the semiconductor device 100 according to the present embodiment, an accurate temperature may be calculated in real time by comparing the resistance values of the parallel resistors and the series resistor.

The method of calculating the temperatures of the semiconductor layer 120 and the highest-temperature heat source of the semiconductor device 100 according to the present embodiment may calculate an average resistance value converging to the design resistance value and a process error of a single resistor based on the average resistance value by measuring each of the resistance values of the plurality of resistors connected in parallel and the single resistor.

Accordingly, in the method of calculating the temperatures of the semiconductor layer 120 and the highest-temperature heat source of the semiconductor device 100 according to the present embodiment, a simulation operation and a precise resistance value measurement operation, which are required during resistor design, can be omitted by calculating the average resistance value converging to the design resistance value and the process error of the single resistor based on the average resistance value.

In addition, the method of calculating the temperatures of the semiconductor layer 120 and the highest-temperature heat source of the semiconductor device 100 according to the present embodiment may more accurately calculate the temperatures of the semiconductor layer 120 and the highest-temperature heat source by applying the offset caused by the process error to the lookup table including temperature information corresponding to resistance values.

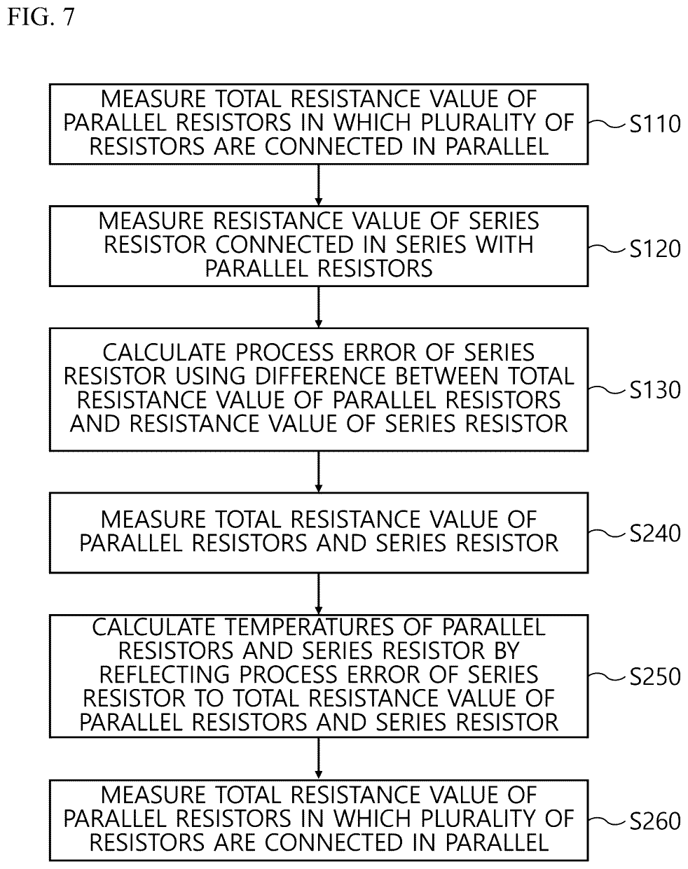

FIG. 7 is a flowchart illustrating a method of calculating a temperature of the semiconductor layer based on temperatures of parallel resistors and a series resistor according to the present disclosure.

Referring to FIG. 7, the method of calculating a temperature using a plurality of resistors according to the present embodiment may further include measuring a total resistance value of the parallel resistors and the series resistor and calculating temperatures of the parallel resistors and the series resistor, in addition to the method of calculating a temperature using a plurality of resistors shown in FIG. 6. In this case, the method may include calculating a temperature of the semiconductor layer based on the temperatures of the parallel resistors and the series resistor, instead of calculating the temperature of the semiconductor layer based only on the temperature of the series resistor. Accordingly, redundant descriptions of configurations substantially the same as those in the method of calculating a temperature using a plurality of resistors shown in FIG. 6 will be omitted.

In operation S240, a total resistance value of parallel resistors and a series resistor is measured. Specifically, the resistance measuring part of the temperature calculation module (not shown) may measure an equivalent resistance value of a plurality of resistors connected in parallel and a resistor connected in series.

In operation S250, temperatures of the parallel resistors and the series resistor are calculated by reflecting a process error of the series resistor to the total resistance value of the parallel resistors and the series resistor. Specifically, the memory of the temperature calculation module (not shown) may include a lookup table that includes a temperature of the resistor corresponding to a design resistance value of the resistor. The processor of the temperature calculation module (not shown) may generate a lookup table including a temperature corresponding to a total equivalent resistance value of the first to third resistors 141, 142, and 143 by applying an offset equal to a process error of the third resistor 143 to the lookup table including a temperature corresponding to the design resistance value. Accordingly, the processor of the temperature calculation module (not shown) may calculate accurate temperatures of the first to third resistors 141, 142, and 143 based on the lookup table reflecting the process error of the third resistor 143.

According to various embodiments of the present invention, the memory of the temperature calculation module (not shown) may include a relationship equation between the resistance value and temperature according to a TCR. Accordingly, the processor of the temperature calculation module (not shown) may calculate the temperatures of the first to third resistors 141, 142, and 143 based on the total equivalent resistance value of the first to third resistors 141, 142, and 143 using the relationship equation between the resistance value and temperature according to a TCR. Accordingly, the processor of the temperature calculation module (not shown) may calculate the temperature based on a resistance value greater than that of either the single resistor or the plurality of parallel resistors, thereby improving the temperature measurement sensitivity.

In operation S260, the temperature of the semiconductor layer is calculated based on the temperatures of the parallel resistors and the series resistor. The memory of the temperature calculation module (not shown) may store a lookup table including a temperature of the semiconductor layer 120 and a temperature of the channel of the transistor 130 corresponding to the temperatures of the first to third resistors 141, 142, and 143. Accordingly, the processor of the temperature calculation module (not shown) may calculate the temperatures of the semiconductor layer 120 and the highest-temperature heat source of the semiconductor device 100 based the temperatures of the first to third resistors 141, 142, and 143, using the lookup table including the temperature of the semiconductor layer 120 and the temperature of the channel of the transistor 130.

The method of calculating the temperatures of the semiconductor layer 120 and the highest-temperature heat source of the semiconductor device 100 according to the present embodiment may improve the sensitivity of resistance value and temperature calculation by calculating the temperature based on the total equivalent resistance value of the plurality of resistors connected in parallel and the resistor connected in series with the plurality of resistors connected in parallel.

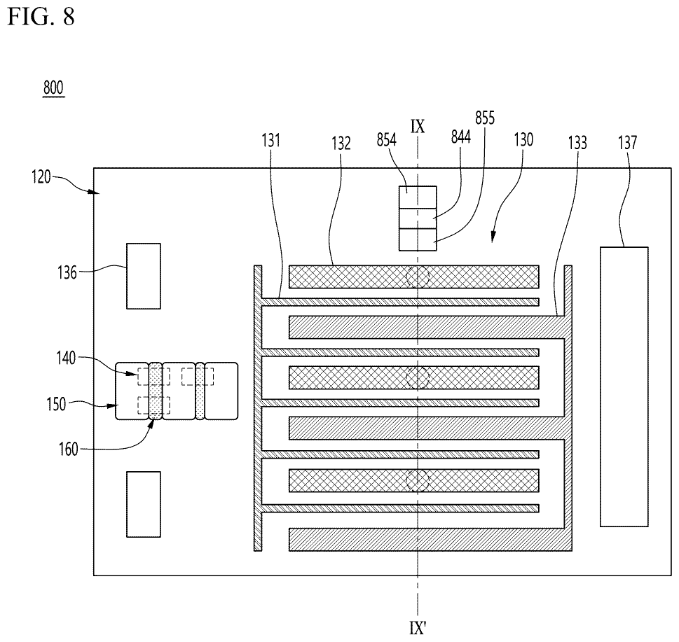

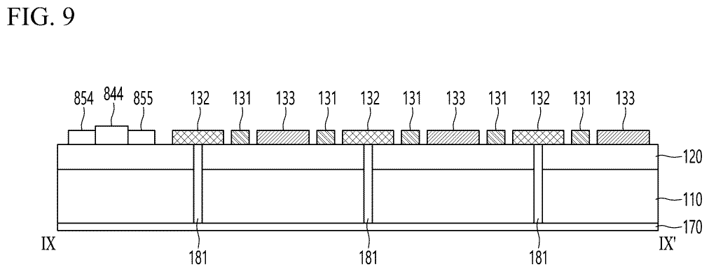

FIG. 8 is a top view illustrating a semiconductor device according to another embodiment of the present disclosure. FIG. 9 is a cross-sectional view of the semiconductor device of FIG. 8 taken along line IX-IX′. Referring to FIGS. 8 and 9, a semiconductor device 800 according to the present embodiment further includes a fourth resistor 844, a fourth temperature measurement pad 854, and a fifth temperature measurement pad 855, in addition to the configurations of the semiconductor device 100 of FIGS. 1 to 5. Accordingly, redundant descriptions of components that are substantially the same as those of the semiconductor device 100 of FIGS. 1 to 5 will be omitted.

The fourth resistor 844 may be a resistive element whose resistance value changes according to a temperature change. Accordingly, a user may monitor a temperature of heat generated in the semiconductor device 800 by measuring changes in a resistance value of the fourth resistor 844.

The fourth resistor 844 may include a material whose electrical properties change according to the temperature. Specifically, the fourth resistor 844 may include a material having a high TCR. For example, the fourth resistor 844 may include a polymer-based or ceramic-based material of a PTC thermistor, a metal oxide material of an NTC thermistor, or a GaN-based material. As the fourth resistor 844 includes a material having a high TCR, the temperature of the fourth resistor 844 may be more accurately calculated based on the resistance value of the fourth resistor 844.

The fourth resistor 844 may have various shapes. For example, the fourth resistor 844 may have a thin-film shape formed through a deposition process, or a protruding shape, i.e., a mesa shape, formed through an etching process. For example, the fourth resistor 844 may be a mesa resistor in which the shape and size of a resistive element are precisely controlled through semiconductor processes. In addition, the fourth resistor 844 may be formed using existing semiconductor manufacturing processes, thereby achieving low manufacturing costs.

Referring to FIG. 8, the fourth resistor 844, the fourth temperature measurement pad 854, and the fifth temperature measurement pad 855 are disposed on another side of the transistor 130, which is spaced apart from the side, on which the resistor part 140 and the temperature measurement pad part 150 are disposed. For example, the resistor part 140 and the temperature measurement pad part 150 may be disposed on the left side of the transistor 130, and the fourth resistor 844, the fourth temperature measurement pad 854, and the fifth temperature measurement pad 855 may be disposed on the upper side of the transistor 130. As the fourth resistor 844, the fourth temperature measurement pad 854, and the fifth temperature measurement pad 855 are disposed on another side spaced apart from the resistor part 140 and the temperature measurement pad part 150, a temperature different from the temperature of the channel of the semiconductor device 100, which is measured through the resistor part 140 and the temperature measurement pad part 150, may be measured. Specifically, the fourth resistor 844, the fourth temperature measurement pad 854, and the fifth temperature measurement pad 855 may be used to measure the overall package temperature of the semiconductor device 100 or the temperature of air surrounding the semiconductor device 100 due to heat generated in the semiconductor device 100.

Referring to FIG. 9, the fourth resistor 844 is disposed on the semiconductor substrate 110. Specifically, the fourth resistor 844 may be disposed on the upper surface of the semiconductor layer 120, or on an upper surface of an insulating layer disposed on the semiconductor layer 120.

Referring to FIGS. 8 and 9, the fourth temperature measurement pad 854 and the fifth temperature measurement pad 855 are disposed on the semiconductor substrate 110. Specifically, the fourth temperature measurement pad 854 and the fifth temperature measurement pad 855 may be disposed on the upper surface of the semiconductor layer 120, or on the upper surface of the insulating layer disposed on the semiconductor layer 120. For example, the fourth temperature measurement pad 854 and the fifth temperature measurement pad 855 may be disposed on the same layer as the fourth resistor 844 disposed on the upper surface of the semiconductor layer 120.

The fourth temperature measurement pad 854 and the fifth temperature measurement pad 855 include a conductive material. Specifically, the fourth temperature measurement pad 854 and the fifth temperature measurement pad 855 may include a material having high electrical conductivity, such as a metal.

The fourth temperature measurement pad 854 and the fifth temperature measurement pad 855 may be electrically connected to the fourth resistor 844. Accordingly, the temperature calculation module (not shown) may be electrically connected to the fourth temperature measurement pad 854 and the fifth temperature measurement pad 855 to apply a current to the fourth resistor 844, thereby measuring the resistance value of the fourth resistor 844 and calculating the temperature of the fourth resistor 844 based on the resistance value of the fourth resistor 844. The temperature of the fourth resistor 844 may be used to calculate a temperature of an outer surface of the semiconductor device 800 or a temperature of air outside the semiconductor device 800.

The semiconductor device 800 according to the present embodiment may include the fourth resistor 844 disposed on the upper surface of the semiconductor layer 120 or on the upper surface of the insulating layer formed on the semiconductor layer 120, and thus may measure the temperature of the outer surface of the semiconductor device 800 or the temperature of air outside the semiconductor device 800. Furthermore, by calculating the temperature of the outer surface of the semiconductor device 800 or the temperature of air outside the semiconductor device 800, more specific temperature information may be provided for monitoring a heat dissipation state of the semiconductor device 800 and for a temperature management system of the semiconductor device 800.

In the present specification, each block may represent a module, segment, or portion of code that includes one or more executable instructions for performing specific logical function(s). It should also be noted that, in some alternative embodiments, the functions mentioned in the blocks may be executed out of the illustrated order. For example, two blocks shown in succession may in fact be executed substantially concurrently or may sometimes be executed in the reverse order depending on the functionality involved.

According to any one of the means for solving the problems of the present invention, a semiconductor device includes a resistor disposed in a semiconductor layer, thereby enabling more accurate measurement of heat generation of the semiconductor layer and a highest-temperature heat source of the semiconductor device.

According to any one of the means for solving the problems of the present invention, a semiconductor device is capable of accurately monitoring temperatures of a semiconductor layer and a highest-temperature heat source in real time, thereby preventing degradation in performance and reduction in lifespan of the semiconductor device.

According to any one of the means for solving the problems of the present invention, a semiconductor device is capable of calculating temperatures of a semiconductor layer and a highest-temperature heat source using a plurality of resistors, thereby minimizing temperature deviations caused by process variations of the resistors.

According to any one of the means for solving the problems of the present invention, a semiconductor device includes a temperature measurement pad that is electrically connected directly to an upper portion of a resistor, thereby enabling a reduced volume and lower manufacturing costs.

According to any one of the means for solving the problems of the present invention, upper portions of a plurality of resistors can be covered with temperature measurement pads and an insulator, thereby enabling more accurate measurement of a temperature of an active region, regardless of the ambient temperature outside a semiconductor device.

The effects obtainable from the present invention are not limited to the effects mentioned above, and other effects not mentioned will be clearly understood by those skilled in the art to which the present invention pertains from the following description.

While the embodiments of the present invention have been described in detail above with reference to the accompanying drawings, the present invention is not necessarily limited to these embodiments, and various changes and modifications may be made without departing from the technical spirit of the present invention. Accordingly, the embodiments disclosed herein are to be considered descriptive and not restrictive of the technical spirit of the present invention, and the scope of the technical spirit of the present invention is not limited by these embodiments. Accordingly, the above-described embodiments should be understood to be exemplary and not limiting in any aspect. The scope of the present invention should be construed by the appended claims along with the full range of equivalents to which such claims are entitled.

What is claimed is:

1. A semiconductor device comprising:
a semiconductor substrate;
a semiconductor layer disposed on the semiconductor substrate;
a plurality of resistors disposed in the semiconductor layer;
at least one electrode layer disposed on the semiconductor layer; and
a first temperature measurement pad, a second temperature measurement pad, and a third temperature measurement pad that are disposed on the semiconductor layer,
wherein the plurality of resistors are electrically connected to at least one of the first temperature measurement pad, the second temperature measurement pad, and the third temperature measurement pad.

2. The semiconductor device of claim 1, wherein the plurality of resistors include a first resistor, a second resistor, and a third resistor,
wherein the first resistor and the second resistor are connected in parallel,
one side of each of the first resistor and the second resistor is electrically connected to the first temperature measurement pad,
the other side of each of the first resistor and the second resistor is electrically connected to the second temperature measurement pad and one side of the third resistor, and
the other side of the third resistor is electrically connected to the third temperature measurement pad.

3. The semiconductor device of claim 2, wherein the first resistor, the second resistor, and the third resistor have the same resistance value.

4. The semiconductor device of claim 2, wherein
the first temperature measurement pad is disposed on each of the first resistor and the second resistor,
the second temperature measurement pad is disposed on each of the first resistor, the second resistor, and the third resistor, and
the third temperature measurement pad is disposed on the third resistor.

5. The semiconductor device of claim 4, further comprising:
a first insulator disposed between the first temperature measurement pad and the second temperature measurement pad; and
a second insulator disposed between the second temperature measurement pad and the third temperature measurement pad,
wherein the first temperature measurement pad, the second temperature measurement pad, and the first insulator cover an entire upper surface of each of the first resistor and the second resistor, and
the second temperature measurement pad, the third temperature measurement pad, and the second insulator cover an entire upper surface of the third resistor.

6. The semiconductor device of claim 2, wherein the at least one electrode layer includes a source electrode, a drain electrode, and a gate electrode.

7. The semiconductor device of claim 6, further comprising:
a ground layer disposed below the semiconductor substrate;
a first via disposed between the source electrode and the ground layer; and
a second via disposed between the third resistor and the ground layer,
wherein the first via has thermal conductivity and electrical conductivity, and is electrically connected to the source electrode and the ground layer.

8. The semiconductor device of claim 7, wherein the second via has thermal conductivity and is thermally connected to the third resistor and the ground layer.

9. The semiconductor device of claim 2, wherein the first resistor, the second resistor, and the third resistor are mesa resistors.

10. The semiconductor device of claim 1, further comprising at least one transistor,
wherein the at least one transistor includes a channel disposed in the semiconductor layer.

11. The semiconductor device of claim 1, further comprising:
a fourth resistor disposed on the semiconductor layer; and
a fourth temperature measurement pad and a fifth temperature measurement pad respectively disposed at both sides of the fourth resistor,
wherein the fourth temperature measurement pad is electrically connected to one side of the fourth resistor, and
the fifth temperature measurement pad is electrically connected to the other side of the fourth resistor.
